(19) United States
(12) Patent Application Publication
(10) Pub. No.: US 2023/0317675 A1
(43) Pub. Date: Oct. 5, 2023

(54) NON-PLANAR PEDESTAL FOR THERMAL COMPRESSION BONDING

(71) Applicant: Intel Corporation, Santa Clara, CA (US)

(72) Inventors: Michael Baker, Gilbert, AZ (US); Zhaozhi Li, Chandler, AZ (US); Feras Eid, Chandler, AZ (US); Pilin Liu, Chandler, AZ (US); Wenhao Li, Chandler, AZ (US)

(73) Assignee: Intel Corporation, Santa Clara, CA (US)

(21) Appl. No.: 17/711,925

(22) Filed: Apr. 1, 2022

(51) Int. Cl. H01L 23/00

(52) U.S. Cl. CPC H01L 24/75; H01L 24/81; H01L 2224/81203; H01L 2224/75983; H01L 2224/75252

(57) ABSTRACT

Microelectronic die package structures formed according to some embodiments may include a thermal compression bonding (TCB) tool including a pedestal having a convex surface to receive a package substrate, a bond head to compress a die against the package substrate, and a heat source thermally coupled to at least one of the pedestal or the bond head.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

Die back side layers, either metallic or composite, may exhibit high thermal conductivities and thus can benefit package heat dissipation and facilitate warpage control during surface mounting of the package to a board, such as a PCB. However, the use of thicker die backside layers (with thicknesses on the order of tens to hundreds of microns) may impose unique challenges during the chip assembly process, such as during thermal compression bonding (TCB).

For example, the die backside layers may possess a coefficient of thermal expansion (CTE) that is larger than that of silicon. This CTE mismatch can result in die warpage during TCB, which may induce a “frowning face” shape, i.e. the die edges may touch the substrate before the center. Failures can occur due to this warpage, such as solder bridging at die corners and/or joint opens forming at die center regions.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1D are cross-sectional views and top views of a non-planar pedestal assembly for use in thermal compression bonding, in accordance with some embodiments.

FIGS. 2A-2F illustrate cross-sectional views and top views of a bond head assembly comprising independently controlled thermal zones for use in thermal compression bonding, in accordance with some embodiments.

FIG. 3 illustrates a flow chart of a process that includes bonding a die to a substrate using a non-planar pedestal for use in a thermal compression bonding system, in accordance with some embodiments.

FIG. 4 illustrates a flow chart of a process that includes bonding a die to a substrate using a bond head comprising independently controlled thermal zones for use in a thermal compression bonding system, in accordance with some embodiments.

FIG. 5 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “thermal compression bonding” (TCB) generally refers to a manufacturing method for IC package assembly by tooling that applies heat and pressure to bond together IC package components such a die and a substrate. Heat may be applied for solder reflow and/or adhesive curing. The tooling may simultaneously apply force to press the components together as a stack, such as a die to an IC package substrate, for example. The pressure may be applied during the heating cycle to increase contact between bonding surfaces, ensuring reliability of the finished IC package. TCB tools generally comprise two platens, with temperature control applied to one or both platens. A substrate, such as a partially assembled IC package substrate, is compressed and held between the platens during a heating cycle, where a controlled force is applied to one or both platens.

Embodiments discussed herein may address problems associated with managing die warpage during a chip attach processes, such as thermal compression bonding (TCB). For example, die backside layers, which are advantageously deployed for benefits of heat dissipation and warpage control during surface mount operations, may possess a coefficient of thermal expansion (CTE) that is larger than that of silicon, or other materials deployed in a die. This CTE mismatch can result in die warpage during TCB and other problems, which lead to failures inclusive of solder bridging at die corners and/or joint opens at die center regions. Die warpage can also occur during TCB processing without the use of die backside layers due to the presence of die front side metal materials and dielectric layers. Discussion begins with embodiments related to utilizing a curved, non-planar pedestal for mitigating die warpage during chip attach processing.

Embodiments herein describe a TCB assembly comprising a curved pedestal surface for use in TCB processing. The curved profile of the pedestal surface enables a substrate profile to be matched with a die profile within a package structure to mitigate warpage during TCB, for example. For example, the curved pedestal surface is to receive the substrate. The substrate, during bonding, matches the curved surface pedestal to, in turn, match a curved die profile due to heating the die during TCB. The curved profile of the substrate may be facilitated by securing the substrate to the curved surface using vacuum and/or heating the pedestal. A TCB tool according to some embodiments herein may include a pedestal comprising a convex surface to receive a package substrate, a bond head to compress a die against the package substrate, and a heat source thermally coupled to at least one of the pedestal or the bond head. For example, the discussed custom pedestals mitigate die warpage during chip attach by having a top surface geometry that enables the substrate profile to match the profile of the die during bonding. Such custom pedestals advantageously reduce failures by leveraging the repeatability of die warpage and the ability of the heated pedestal to constrain the substrate to a desired profile.

In some embodiments, the pedestal may comprise a non-linear profile. In some embodiments, the pedestal may comprise a convex profile. In some embodiments, a radius of curvature of the pedestal may be defined such that a substrate mounted to the surface of the pedestal comprise a non-linear profile.

The TCB assemblies described herein may be assembled and/or fabricated with one or more of the features or attributes provided in accordance with various embodiments. A number of different assembly and/or fabrication methods may be practiced to generate die and substrate structures having matching chip gaps prior to chip attach according to one or more of the features or attributes described herein.

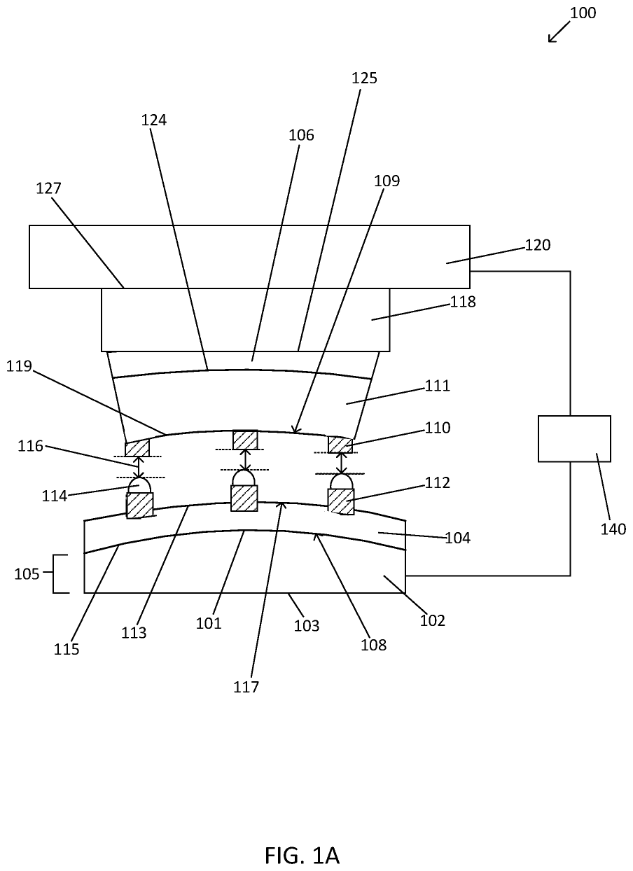

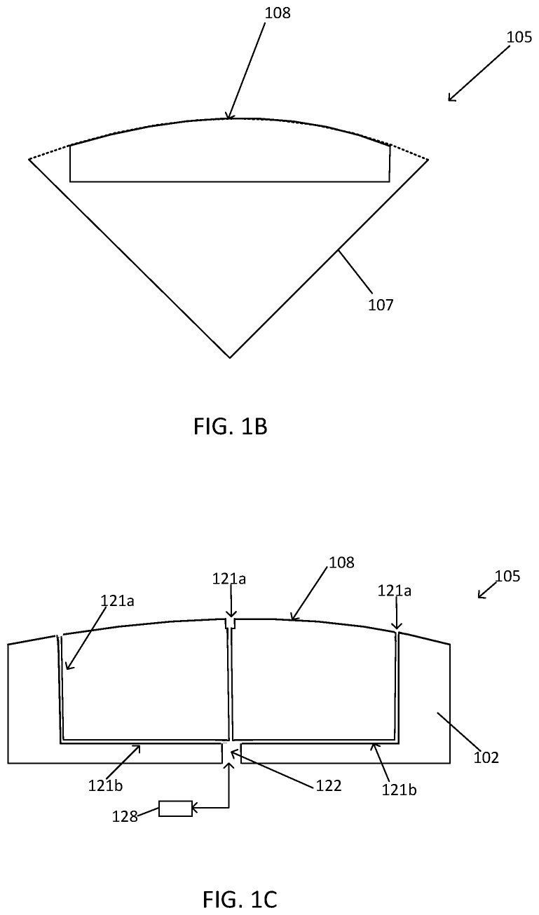

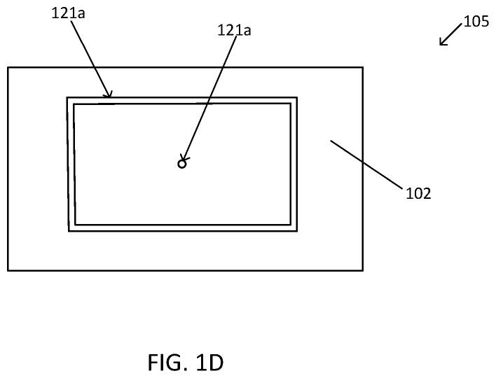

FIGS. 1A-1D depict embodiments of a TCB assembly for attaching a die to a substrate using a TCB process. The TCB tool comprises a heated pedestal which is employed to secure a microelectronic substrate during a bonding process. The TCB tool comprises a pedestal having a surface geometry which enables the substrate curvature profile to match a curvature profile of a die to be bonded to the substrate during a TCB process.

FIG. 1A is a cross-sectional view of portions of a TCB tool assembly 100 according to some embodiments herein. A pedestal 105 may comprise a first side 101, a second side 103, and a body 102. The second side 103 may comprise a planar surface. The first side 101 of the pedestal 105 may comprise a non-planar surface 108, which may comprise a curved surface 108 in some embodiments. In some embodiments, the non-planar surface 108 may comprise a convex surface 108. In some embodiments, the pedestal 105 may comprise any suitable metallic material. In some embodiments, the pedestal 105 may comprise such materials as aluminum, copper, steel or combinations thereof.

The pedestal 105 may receive a workpiece, such as a substrate 104 on the curved surface 108 of the pedestal 105. In some embodiments, the substrate 104 may comprise a microelectronic package substrate to which any number of dies may be placed upon. The substrate 104 may comprise conductive material with dielectric material interspersed within the substrate 104. The substrate 104 may additionally comprise integrated circuitry fabricated according to any suitable microelectronic technology such as complementary metal oxide semiconductor (CMOS), SiGe, III-V or III-N HEMTs, etc.) techniques or others. For example, the substrate 104 may include any number of active or passive devices. The substrate 104 may comprise a first side 113 and a second side 115. The second side 115 of the substrate 104 may be on the curved surface 108 of the substrate 104.

In some embodiments, the substrate 104 may have a curvature 117 that is substantially the same as the curvature 108 of the pedestal 105. The pedestal 105 may constrain the substrate 104 to have substantially the same curvature 108 (to be described subsequently herein) as the first surface 101 of the pedestal 105. In some embodiments, the particular shape/curvature 108 of the pedestal 105 is such that the curvature 108 may have a predetermined magnitude. In some embodiments, the predetermined magnitude of the curvature 108 of the pedestal 105 may be used to match a particular die warpage (such as die 111) that may occur after a particular thermal cycle(s).

The first side 113 of the substrate 104 may comprise conductive substrate pads 112, in some embodiments. The substrate pads 112 may comprise any suitable conductive material such as copper or copper alloys, in some embodiments. A conductive interconnect structure 114 may be on each substrate pad 112. As used herein, the term conductive interconnect structure indicates any structure or conductive element for coupling to an outside die or other device. In an embodiment, the conductive interconnect structures 114 may comprise a solder structure. For example, the conductive interconnect structures 114 may be solder balls. As used herein, the term solder balls indicates an interconnect structure prior to or after reflow. The solder structures may comprise one or more of silver, tin, copper, and combinations thereof.

A bond head 120 may be mechanically and/or electrically coupled to the pedestal 105 and may receive a die 111. In an embodiment, a bond head nozzle 118 may be coupled to the bond head 120 and may comprise vacuum channels (not shown) which may hold the die 111 by vacuum to the bond head 120. In an embodiment, the die 111 may be coupled to a first side 125 of the bond head nozzle 118, and a second side 127 of the bond head nozzle 118 may be on the bond head 120. The die 111 may comprise any appropriate die/device, including, but not limited to, a microprocessor, a graphics device, a wireless device, a memory device, an application specific integrated circuit, a transceiver device, an input/output device, combinations thereof, stacks thereof, or the like. The die 111 may comprise a first side 119 and a second side 124, such that the second side 124 of the die 111 is coupled to the first side 125 of the bond head nozzle 118.

In some embodiments, a die backside layer 106 may optionally be between the bond head 120 and the second side 124 of the die 111. The die backside layer 106 may comprise a metallic or a composite material and may comprise a material with a high thermal conductivity. The die backside layer 106 provides heat dissipation and warpage control during assembly of the package to the board, such as during a surface mount process of the package 100 onto a board (subsequent to the illustrated die to substrate bonding). In an embodiment, the surface mount process may comprise a reflow process, as is known in the art. In some embodiments, the die backside layer 106 may comprise at least one of copper, aluminum, silver, gold, diamond materials, aluminum nitride, silicon carbide or combinations thereof. In some embodiments, the die backside layer 106 may comprise a thickness between about 50 microns to about 500 microns.

In some embodiments, the first side 119 of the die 111 may comprise conductive die pads 110. The conductive die pads 110 may comprise any suitable conductive material such as copper or copper alloys, in some embodiments. In some embodiments, the first side 119 of the die 111 may comprise a die warpage profile 109 which may comprise a concave warpage profile 109. In embodiments, the curvature 108 of the pedestal 105 may be predetermined to constrain the substrate 104 to a substrate curvature 117 such that a chip gap 116 between the die pads 110 on the die 111 and the conductive interconnect structures 112 on the substrate 104 may be uniform across the die 111 and substrate 104.

In some embodiments, the predetermined magnitude of the pedestal curvature 108 may be used for a particular IC package type and measured die warpage that occurs after a particular thermal cycle. In some embodiments, the pedestal 105 and optionally the bond head 120 may be heated with a heat source/temperature control device 140 during a TCB process. In some embodiments, the heat source 140 may be integral with the pedestal 105. By matching the substrate curvature to die thermal warpage profile the chip gaps 116 may be matched. takes advantage of the repeatability of die warpage and heated pedestal ability to constrain the substrate to a profile. In an embodiment, a chip gap 116 in a center region of the die/substrate 111/104 is substantially the same as a chip gap 116 in a peripheral region of the die/substrate 111/104.

In FIG. 1B, a cross-sectional view of the pedestal 105 comprising a radius of curvature 107 that may be predetermined based on a particular die warpage profile, such as the die warpage profile 109 as shown for die 111 in FIG. 1A. In some embodiments, the radius of curvature 107 may comprise between about 0.2 m to about 150 m. In some embodiments, the radius of curvature may comprise between about 1 m and 75 m. In some embodiments, a substrate 104 may be constrained to the predetermined curvature 108 of the by the pedestal 105.

In some embodiments, substrate 104 is secured to the non-planar surface 108 of pedestal 105 via vacuum. For example, in FIG. 1C, the pedestal 105 may comprise one or more vacuum channels 121 that extend through the body 102 of the pedestal 105. In an embodiment, the vacuum channels 121 may comprise first portions 121a that extends vertically through the body 102 of the pedestal 105, and second portions 121b that extends horizontally through the pedestal 105 body 102. The vacuum channels 121 may be in any suitable configuration within the body 102 of the pedestal and may further comprise at least one vacuum port 122 that may be coupled to a vacuum source 128. The vacuum channels 121 may be employed to provide suction to constrain the substrate 104 to the pedestal curvature 108 in some embodiments.

FIG. 1D depicts a plan view of a portion of the pedestal 105 where vacuum ports 121a are shown. As shown in FIG. 1D, in some embodiments, portions 121a may be in a rectangular pattern that surrounds a center region of pedestal 105. For example, some of portions 121a may form a rectangular annulus. The rectangular annulus may be centered on a center point of a curvature non-planar surface 108 of pedestal 105.

As discussed, embodiments herein include a TCB tool comprising a heated, curved pedestal employed to match a substrate curvature with a die warpage profile during TCB, For example, heating the pedestal may aid in warping the substrate 104 to the curvature of non-planar surface 108.

The TCB tool embodiments herein are designed to avoid failures inclusive of solder bridging at die corners and/or joint opens at die center regions. Discussion now turns to embodiments related to a TCB tool comprising a bond head designed to mitigate die warpage during TCB.

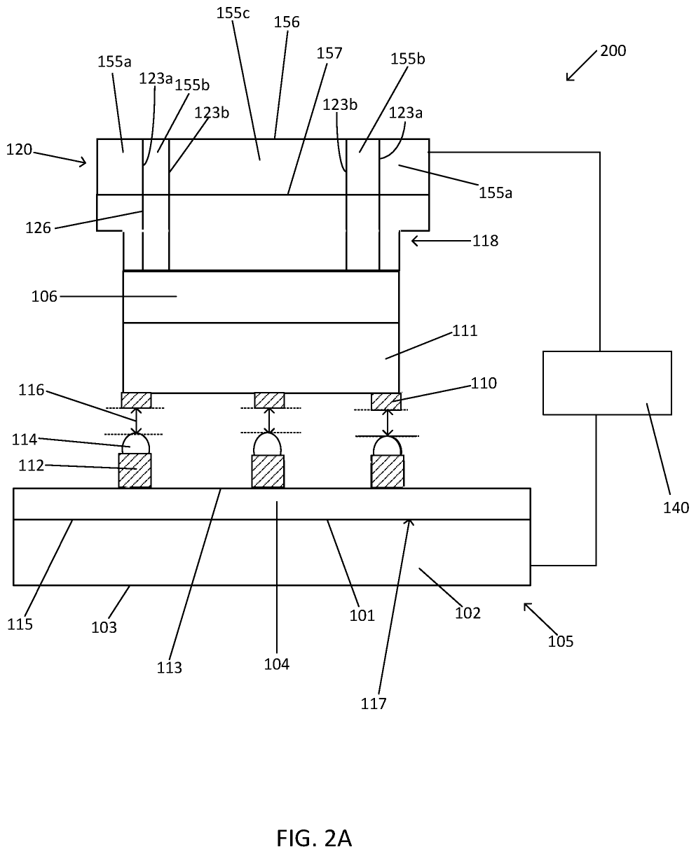

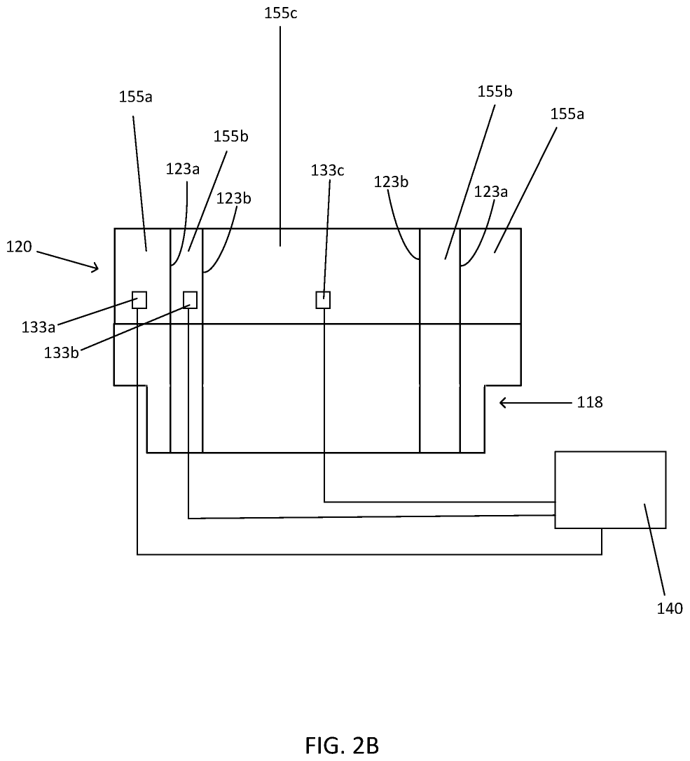

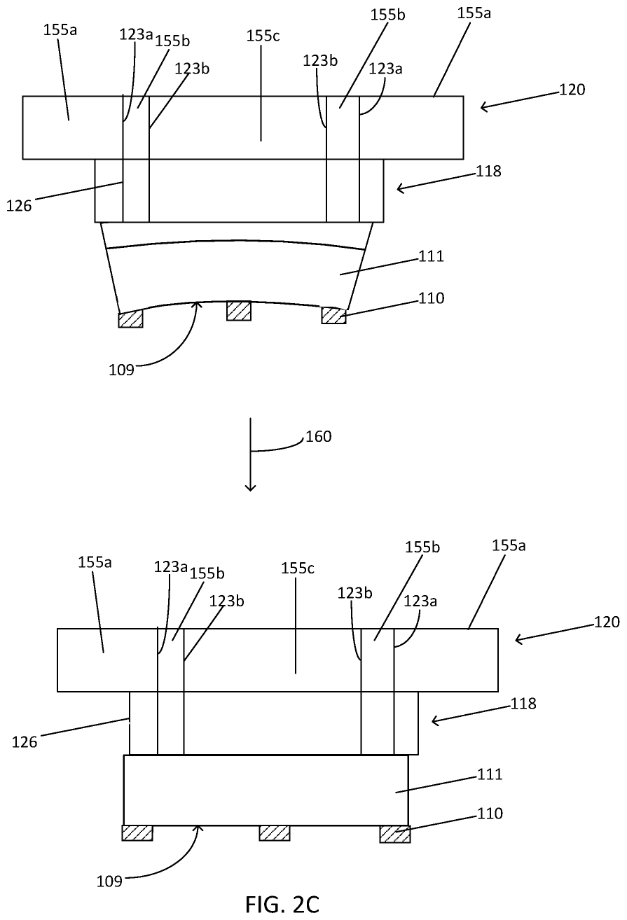

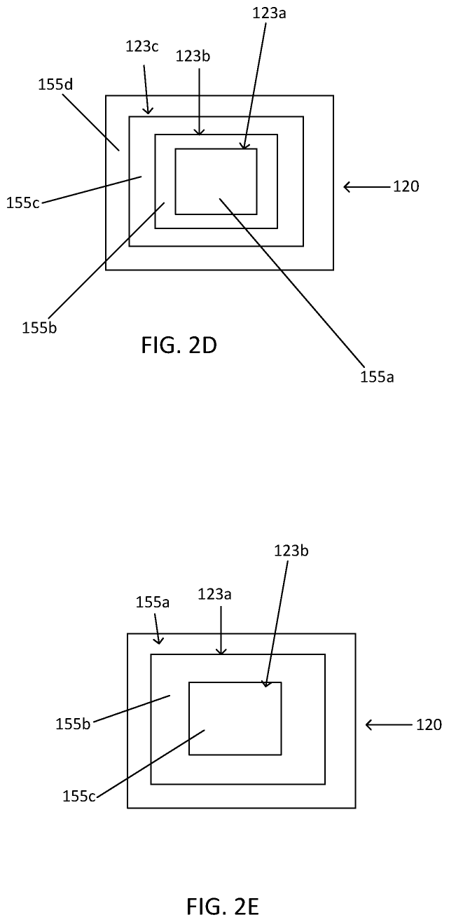

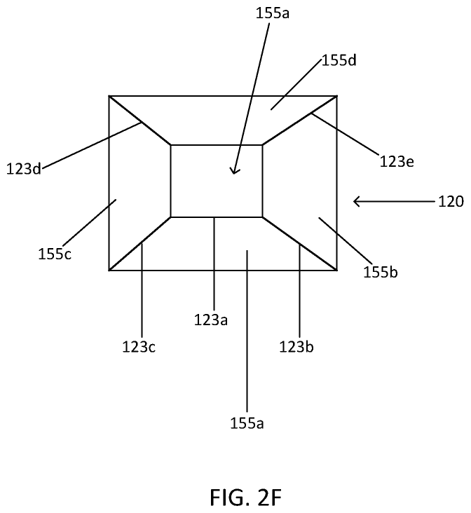

FIGS. 2A-2E depict embodiments of a TCB assembly for attaching a die to a substrate having isolated thermal zones that are controlled independently, thus enabling modulation of die or package warpage. FIG. 2A depicts a cross-sectional view of a portion of a TCB tool assembly 200 according to some embodiments herein. A pedestal 105 may comprise a first side 101, a second side 103, and a body 102. In some embodiments, the pedestal 105 may comprise any suitable metallic material. In some embodiments, the pedestal 105 may comprise such materials as aluminum, copper, steel or combinations thereof.

The pedestal 105 may receive a substrate 104 on the first side 101 of the pedestal 105. The first side 101 of the pedestal 105 may comprise a planar surface in some embodiments. In some embodiments, the substrate 104 may comprise a microelectronic package substrate to which any number of dies may be placed upon, in some embodiments. The substrate 104 may comprise conductive material with dielectric material interspersed within the substrate 104. The substrate 104 may additionally comprise integrated circuitry fabricated according to any suitable microelectronic technology such as complementary metal oxide semiconductor (CMOS), SiGe, III-V or III-N HEMTs, etc.) techniques or others. For example, the substrate 104 may include any number of active or passive devices. The substrate 104 may comprise a first side 113 and a second side 115. The second side 115 of the substrate 104 may be on the first side 101 of the pedestal 105.

The first side 113 of the substrate 104 may comprise conductive substrate pads 112, in some embodiments. The substrate pads 112 may comprise any suitable conductive material such as copper or copper alloys, in some embodiments. A conductive interconnect structure 114 may be on each substrate pad 112. In an embodiment, the conductive interconnect structures 114 may comprise a solder structure. For example, the conductive interconnect structures 114 may be solder balls. The solder structures may comprise one or more of silver, tin, copper, and combinations thereof.

A bond head 120 may be mechanically and/or electrically coupled to the pedestal 105 and may receive a die 111. In an embodiment, a bond head nozzle 118 may be coupled to the bond head 120 and may comprise vacuum channels (not shown) which may hold the die 111 by vacuum to the bond head 120. In an embodiment, the die 111 may be coupled to a first side 125 of the bond head nozzle 118, and a second side 127 of the bond head nozzle 118 may be on the bond head 120. The die 111 may comprise any appropriate die/device, including, but not limited to, a microprocessor, a chipset, a graphics device, a wireless device, a memory device, an application specific integrated circuit, a transceiver device, an input/output device, combinations thereof, stacks thereof, or the like.

The die 111 may comprise a first side 119 and a second side 124, such that the second side 124 of the die 111 is coupled to the first side 125 of the bond head nozzle 118. In some embodiments, a die backside layer 106 (similar to the die backside layer of FIG. 1A, for example) may optionally be between the bond head 120 and the second side 124 of the die 111.

In some embodiments, the first side 119 of the die 111 may comprise conductive die pads 110. The conductive die pads 110 may comprise any suitable conductive material such as copper or copper alloys, in some embodiments. During bonding, the die 111 may tend to warp as discussed herein. Such undesirable warpage may be mitigated or counteracted entirely by the use of independently controlled thermal zones 155 (shown as thermal zones 155a-155e) in the bond head 120. Each thermal zone 155a-155e may be separated by a thermal separator 123. The thermal separators 123 extend through the body of the bond head 120 from a first side 156 of the bond head 120 to a second side 157 of the bond head 120.

For example, as shown in FIG. 2A, a first thermal zone 155a and a second thermal zone 155b may be separated by a first thermal separator 123a. The second thermal zone 155b and a third thermal zone 155c may be separated by a second thermal separator 123b. A plan view of the bond head 120 with thermal zones 155a-155c and thermal separators 123a, 123b is shown in FIG. 2E.

Returning back to FIG. 2A, in an embodiment, the thermal separators 123 may comprise any material suitable for maintaining a difference in temperature between two adjacent thermal zones 123. In some embodiments, the thermal separators are gaps filled with the ambient such as air or vacuum in contexts when the thermal separators are further used as vacuum channels. For example, the thermal separator 123 may comprise a vacuum channel and may be coupled to a vacuum source. In some embodiments, the thermal separators 123 may comprise solid or semi-solid materials inclusive of (very low thermal conductive material, thermal plastics, ceramic, epoxies, or glass. In some embodiments, the thermal zones 155 may comprise a material with a much higher thermal conductivity than a thermal conductivity of the thermal separator 123 material. In some embodiments, the thermal conductivity of the material of thermal zones 155 is not less times than 100 times the thermal conductivity of the material of thermal separator 123. In some embodiments, the thermal conductivity of the material of thermal zones 155 is not less times than 1,000 times the thermal conductivity of the material of thermal separator 123. In some embodiments, the thermal conductivity of the material of thermal zones 155 is not less times than 1,500 times the thermal conductivity of the material of thermal separator 123.

In some embodiments, the bond head nozzle 118 may comprise one or more nozzle channels 126. The nozzle channels 126 extend through the body of the bond head nozzle 118 and individual nozzle channels 126 may be coupled with and in direct physical contact with individual thermal separators 123. The nozzle channels 126 may comprise vacuum channels in some embodiments and may be used to hold the die 111 onto the bond head 120. In an embodiment, the nozzle channels 126 may be in fluid communication with the thermal separators 123. The bond head nozzle 118 may comprise any suitable material in some embodiments, and in some embodiments may comprise aluminum nitride, silicon carbide, or combinations thereof.

FIG. 2B depicts a more detailed cross-sectional view of the bond head 120 and the bond head nozzle 118 coupled thereto. Each thermal zone 155a-155c may comprise a thermal heating element 133a-133c within or on the body of the bond head 120, in an embodiment. The exact location and number of the thermal heating elements 133 may be positioned and determined according to the particular design requirements of a particular application. A temperature of each thermal zone 155a-155c may be independently controlled by the corresponding heating elements 133a-133c by any suitable device such as temperature control device 140.

For example during TCB, the first thermal zone 155a may be at a first temperature, and the second thermal zone 155b may be at a second temperature, with the temperatures maintained, in part, by being separated from each other by the first thermal separator 123a. The first and second temperatures may be maintained by the thermal heating elements 133a and 133b and may be independently controlled by the temperature control device 140. In some embodiments, a first thermal zone 155c may be in a central region of the bond head 120 and a second thermal zone 155a may be in a peripheral region of the bond head 120. In some embodiments, during TCB the first thermal zone 155c may be heated to a greater temperature than the second thermal zone 155a.

In FIG. 2C, embodiments are depicted in which a die warpage is modified by the independently controlled thermal zones 155 of the bond head 120 in order to minimize the chip gap variation across a substrate and die. In FIG. 2C, a die 111 may be received and may be coupled to the bond head 120. In some embodiments, the die 111 may be held in place by vacuum/nozzle channels 126 of the bond head nozzle 118. The die 111 may tend toward a die warpage profile 109, which may comprise a curvature due to prior temperature cycling, metal and dielectric layers on the front side of the die 111, the presence of a die backside layer, etc.

Upon applying different amounts of heat to the independent thermal zones 155a-155c during an optimization process 160, the die warpage profile 109 of the die 111 may be modified such that it may be matched to a substrate profile (i.e., a relatively flat profile), as depicted in FIG. 2A. By matching the die warpage profile to the substrate profile prior to performing TCB, the chip gap across the substrate or across the die may be substantially the same, thus improving yield and reliability of devices utilizing the embodiments herein.

FIG. 2D depicts a top view of a bond head design including thermal separators 123 and thermal zones 155, according to embodiments. In an embodiment, the bond head 120 may comprise a rectangular first thermal zone 155a, a rectangular annulus second thermal zone 155b surrounding the first thermal zone 155a, a rectangular annulus third thermal zone 155c surrounding the second thermal zone 155b, and a rectangular annulus fourth thermal zone 155d surrounding the third thermal zone 155c, each separated by a thermal separator 123a, 123b, 123c respectively. In some embodiments, a first thermal zone may be surrounded by a plurality of rectangular thermal zones, each separated by a thermal separator 123, as shown in FIG. 2E. In some embodiments, during TCB, the first thermal zone 155a is at a higher temperature than the second thermal zone 155b, which is at a higher temperature than the third thermal zone 155c, which is at a higher temperature than the fourth thermal zone 155d. However any suitable temperature profiles may be deployed.

FIG. 2F depicts a top view of a bond head design including thermal separators 123 and thermal zones 155, according to embodiments. In an embodiment, the bond head 120 may comprise a rectangular first thermal zone 155a with a rectangular first thermal separator 123a, extending through the body of the bond head 120. Thermal separators 123b-123e each extend from the four corners of the rectangular first separator 123a. Thermal zones 155b-155e each extend at least partially through the body of the bond head 120. In some embodiments, thermal separators 123a, 123b, 123c extend entirely through a thickness of bond head 120. In some embodiments, thermal separators 123a, 123b, 123c extend from second side 157 not less than halfway through a thickness of bond head 120. In some embodiments, thermal separators 123a, 123b, 123c extend from second side 157 not less than three-quarters through a thickness of bond head 120. In some embodiments, thermal separators 123a, 123b, 123c extend from second side 157 not less 95% through a thickness of bond head 120.

Discussion now turns to operations for assembling and/or fabricating the discussed structures.

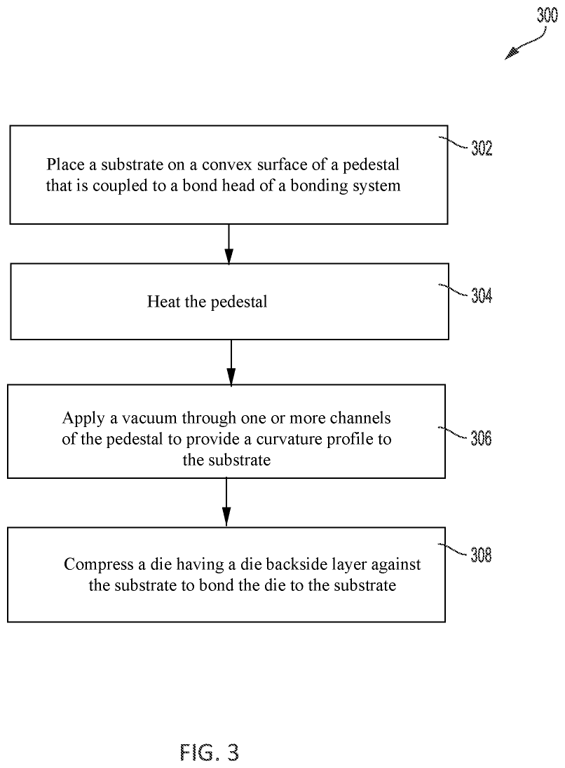

FIG. 3 is a flow chart of a process 300 of fabricating a microelectronic die package structure according to some embodiments. For example, process 300 may be used to fabricate any of the microelectronic die package structures of FIGS. 1A-1D.

As set forth in block 302, a substrate, such as a package substrate, is placed on a convex surface of a pedestal that is coupled to a bond head of a bonding system. The package substrate may be any substrate discussed herein having any number and layout of interconnect structures (e.g., solder balls). For example, one or more conductive interconnect structures may be formed on a surface of a substrate. The substrate may further include substrate pads and solder balls on each individual substrate pad. The curvature of the convex surface of the pedestal may be predetermined so that it may be matched to a curvature of a die to be bonded to the substrate during a TCB chip attach process. In some embodiments, the convex surface is to provide a matching curvature profile of the substrate to a warpage profile of the die during the compressing. The pedestal is coupled to a bond head which receives a die to be bonded to the substrate. The pedestal comprises a portion of a TCB tool assembly.

As set forth in block 304, the pedestal may be heated. In some embodiments, a heating device may be coupled to the pedestal, such that the temperature of the pedestal may be controlled during the TCB process. Optionally, a bond head that is coupled to the pedestal may be heated as well. In some embodiments, the heating device may be integral to the pedestal. As discussed, heating the pedestal may aid in warping the substrate to the curvature of the non-planar or convex surface.

As set forth in block 306, a vacuum may be applied through one or more channels of the pedestal to provide a curvature profile to the substrate. The vacuum channels may comprise any suitable design, such that the substrate is constrained to a die warpage profile. The die may comprise any suitable microelectronic device to be attached to the substrate during a TCB process. The die warpage is repeatable such that the pedestal curvature may be designed to constrain the substrate curvature to match the die curvature. The first side of the die includes bond pads or similar structures to couple to the conductive structures on the first side (e.g., a front side) of the substrate. Furthermore, the die may include a die backside layer on a second side (e.g., back side) of the die, opposite the first side.

As set forth in block 308, the die may be compressed to bond the die to the substrate. The die is bonded to the substrate to couple the conductive interconnect structures to the front side of the die (e.g., via the bond pads or similar structures). Processing may continue with surface mounting of the bonded die/substrate to a board such as a printed circuit board or motherboard with the advantageous die backside layer providing heat dissipation and warpage control.

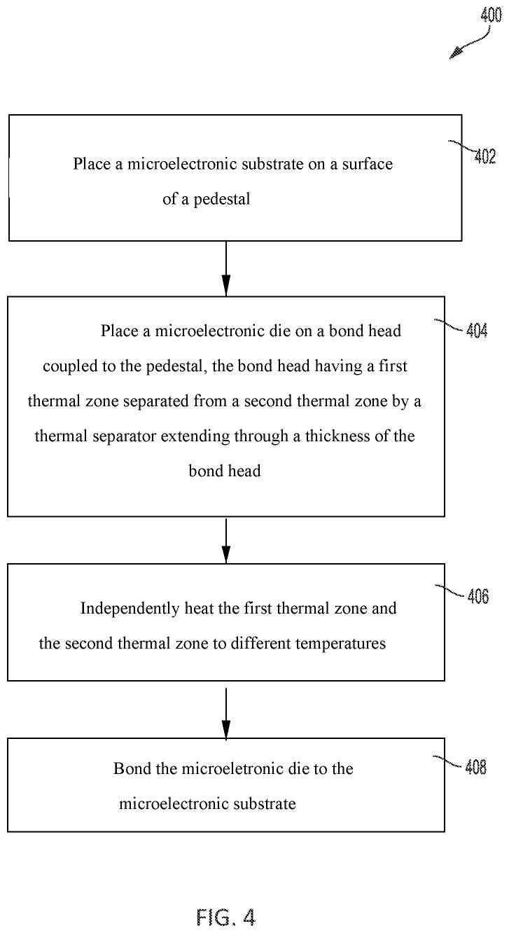

FIG. 4 is a flow chart of a process 400 of fabricating a microelectronic die package structure according to some embodiments. For example, process 400 may be used to fabricate any of the microelectronic die package structures of FIGS. 2A-2F.

As set forth in block 402, a microelectronic substrate is placed on a surface of a pedestal. The substrate may be a package substrate and may include a plurality of solder balls on a surface of the substrate, to be bonded to a die during a TCB process.

As set forth in block 404, a microelectronic die may be placed on a bond head coupled to the pedestal, the bond head having a first thermal zone separated from a second thermal zone by a thermal separator extending through a thickness of the bond head. The thermal zones extend vertically through the body of the bond head from a first side of the bond head to a second side of the bond head. Each thermal zone may have a heating element for independent temperature control.

As set forth in block 406, the first thermal zone and the second thermal zone are independently heated to different temperatures in order to modify the die warpage to match a chip gap across the substrate surface and across the die surface. In an embodiment, the first thermal zone is at a central region of the bond head and is heated to a greater temperature than the second thermal zone, which is at a peripheral region of the bond head. In another embodiment, a first temperature of the first thermal zone is not less than 20 degrees greater than a second a second temperature of the second thermal zone.

As set forth in block 408, the die may be bonded to the substrate to couple the conductive interconnect structures of the substrate to the front side of the die (e.g., via the die conductive features, bond pads or similar structures). In some embodiments, a TCB process may be employed to bond the die to the substrate by applying a compressive force to the microelectronic die and the microelectronic substrate. During such thermal compression bonding, due to the discussed CTE mismatch between the die and the die backside layer, the die may tend to warp, which is mitigated by the modification of the die warpage profile at operation 406. Processing may continue with surface mounting of the bonded die/substrate to a board such as a printed circuit board or motherboard.

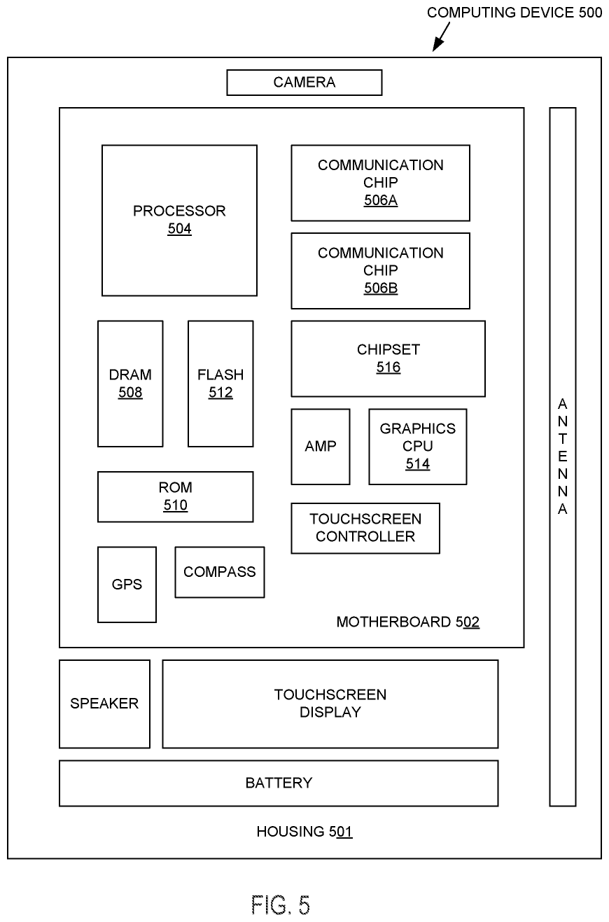

FIG. 5 illustrates an electronic or computing device 500 in accordance with one or more implementations of the present description. The computing device 500 may include a housing 501 having a board 502 disposed therein. The computing device 500 may include a number of integrated circuit components, including but not limited to a processor 504, at least one communication chip 506A, 506B, volatile memory 508 (e.g., DRAM), non-volatile memory 510 (e.g., ROM), flash memory 512, a graphics processor or CPU 514, a digital signal processor (not shown), a crypto processor (not shown), a chipset 516, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 502. In some implementations, at least one of the integrated circuit components may be a part of the processor 504.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an electronic substrate having a die on a substrate, wherein a first side of a die is coupled to the one or more conductive interconnect structures. A die backside layer is on the second side of the die.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-5. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein a first example is a thermal compression bonding (TCB) tool, comprising a pedestal comprising a convex surface to receive a package substrate, bond head to compress a die against the package substrate, and a heat source thermally coupled to at least one of the pedestal or the bond head.

In second examples, the first example can optionally include wherein the convex surface of the pedestal has a radius of curvature in the range of 0.2 meters to 150 meters.

In third examples, for any of the second examples wherein the convex surface of the pedestal has a radius of curvature in the range of 1 meter to 75 meters.

In fourth examples, for any of the first examples wherein a curvature profile of the convex surface is to match to a warpage profile of the die during bonding.

In fifth examples, for any of the fourth examples wherein the warpage profile is based on a die backside layer on a surface of the die opposite the package substrate during bonding.

In sixth examples, for any of the first examples wherein the pedestal comprises one or more vacuum channels extending through a body of the pedestal.

In seventh examples, for any of the sixth examples wherein the vacuum channels are to constrain the substrate to the curvature profile of the convex pedestal surface.

In eighth examples, for any of the first examples wherein the heat source is integral to the pedestal.

In ninth examples, for any of the first examples wherein the pedestal comprises a metal or metal alloy.

In tenth example is a thermal bonding compression (TCB) system, comprising a bond head to compress a die to a package substrate, a platform opposite the bond head, wherein the platform comprises a non-planar surface to receive the package substrate, one or more vacuum channels extending through the body of the platform to secure the package substrate during bonding to the die, and a heat source integral to the pedestal.

In eleventh examples, for any of the tenth examples further comprising a temperature control device thermally coupled to the heat source.

In twelfth examples, for any of the tenth examples wherein the surface of the platform comprises a convex curvature to receive the package substrate.

In thirteenth examples, for any of the twelfth examples, wherein the convex surface of the pedestal has a radius of curvature in the range of 0.2 meters to 150 meters.

In fourteenth examples, for any of the twelfth examples wherein a curvature profile of the convex surface is to match to a warpage profile of the die during bonding.

In fifteenth examples, for any of the tenth examples wherein the platform comprises at least one of steel, aluminum or copper.

In sixteenth examples, a method of thermal compression bonding, the method comprising placing a substrate on a convex surface of a pedestal, wherein the pedestal is coupled to a bond head of a bonding system, heating the pedestal, applying a vacuum through one or more channels of the pedestal to provide a curvature profile to the substrate, and compressing a die comprising a die backside layer against the substrate to bond the die to the substrate.

In seventeenth examples, for any of the sixteenth examples wherein the convex surface of the pedestal has a radius of curvature in the range of 0.2 meters to 150 meters.

In eighteenth examples, for any of the sixteenth examples wherein the convex surface is to provide a matching curvature profile of the substrate to a warpage profile of the die during the compressing.

In nineteenth examples for any of the eighteenth examples wherein the matching curvature profile of the substrate to the warpage profile of the die is provided by matching a chip gap across the substrate, wherein the chip gap comprises a distance between a die pad on the die and a solder interconnect structure on the substrate.

In twentieth examples for any of the nineteenth examples wherein the chip gap is substantially the same in peripheral regions of the substrate as in central regions of the substrate.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. A thermal compression bonding (TCB) tool, comprising:
a pedestal comprising a convex surface to receive a package substrate;
a bond head to compress a die against the package substrate; and
a heat source thermally coupled to at least one of the pedestal or the bond head.

2. The TCB tool of claim 1, wherein the convex surface of the pedestal has a radius of curvature in the range of 0.2 meters to 150 meters.

3. The TCB tool of claim 2, wherein the convex surface of the pedestal has a radius of curvature in the range of 1 meter to 75 meters.

4. The TCB tool of claim 1, wherein a curvature profile of the convex surface is to match to a warpage profile of the die during bonding.

5. The TCB tool of claim 4, wherein the warpage profile is based on a die backside layer on a surface of the die opposite the package substrate during bonding.

6. The TCB tool of claim 1, wherein the pedestal comprises one or more vacuum channels extending through a body of the pedestal.

7. The TCB tool of claim 6 wherein the vacuum channels are to constrain the substrate to the curvature profile of the convex pedestal surface.

8. The TCB tool of claim 1, wherein the heat source is integral to the pedestal.

9. The TCB tool of claim 1, wherein the pedestal comprises a metal or metal alloy.

10. A thermal bonding compression (TCB) system, comprising;
a bond head to compress a die to a package substrate;
a platform opposite the bond head, wherein the platform comprises a non-planar surface to receive the package substrate;
one or more vacuum channels extending through the body of the platform to secure the package substrate during bonding to the die; and
a heat source integral to the pedestal.

11. The TCB system of claim 10, further comprising:
a temperature control device thermally coupled to the heat source.

12. The TCB system of claim 10, wherein the surface of the platform comprises a convex curvature to receive the package substrate.

13. The TCB tool of claim 12, wherein the convex surface of the pedestal has a radius of curvature in the range of 0.2 meters to 150 meters.

14. The TCB system of claim 12, wherein a curvature profile of the convex surface is to match to a warpage profile of the die during bonding.

15. The TCB system of claim 10, wherein the platform comprises at least one of steel, aluminum or copper.

16. A method of thermal compression bonding, the method comprising:
placing a substrate on a convex surface of a pedestal, wherein the pedestal is coupled to a bond head of a bonding system;
heating the pedestal;
applying a vacuum through one or more channels of the pedestal to provide a curvature profile to the substrate; and
compressing a die comprising a die backside layer against the substrate to bond the die to the substrate.

17. The method of claim 16, wherein the convex surface of the pedestal has a radius of curvature in the range of 0.2 meters to 150 meters.

18. The method of claim 16, wherein the convex surface is to provide a matching curvature profile of the substrate to a warpage profile of the die during the compressing.

19. The method of claim 18, wherein the matching curvature profile of the substrate to the warpage profile of the die is provided by matching a chip gap across the substrate, wherein the chip gap comprises a distance between a die pad on the die and a solder interconnect structure on the substrate.

20. The method of claim 19, wherein the chip gap is substantially the same in peripheral regions of the substrate as in central regions of the substrate.
